(19) United States
(12) Patent Application Publication
(10) Pub. No.: US 2025/0314942 A1
(43) Pub. Date: Oct. 9, 2025

(54) FLEXIBLE DISPLAY DEVICE

(71) Applicant: E Ink Holdings Inc., HSINCHU (TW)

(72) Inventors: Chia-Chun YEH, HSINCHU (TW); Yi-Sheng LIN, HSINCHU (TW); Yi-Shou TSAI, HSINCHU (TW); Chen-Chu TSAI, HSINCHU (TW)

(21) Appl. No.: 19/097,880

(22) Filed: Apr. 2, 2025

(30) Foreign Application Priority Data
Apr. 3, 2024 (TW) 113112844

(51) Int. Cl. G02F 1/16755; H10K 59/80; H10K 102/00

(52) U.S. Cl. CPC G02F 1/16755; H10K 59/873; H10K 2102/311

(57) ABSTRACT

A flexible display device includes a flexible substrate, a dielectric stack, a display medium layer, a sealant, and a protection sheet. The dielectric stack includes plural dielectric layers stacked on the flexible substrate. The dielectric stack has a patterned trench to define plural island structures. Each of the island structures is surrounded by the patterned trench. The dielectric stack includes a first portion and a second portion respectively at two opposite sides of the patterned trench. The display medium layer is located on the first portion of the dielectric stack to define a display area. The sealant covers the second portion of the dielectric stack, the patterned trench, and the island structures, and extends to a sidewall of the display medium layer. The protection sheet is located on the sealant and the display medium layer.

### CROSS-REFERENCE TO RELATED APPLICATION

This application claims priority to Taiwan Application Serial Number 113112844, filed Apr. 3, 2024, which is herein incorporated by reference.

### BACKGROUND

### Field of Invention

The present disclosure relates to a flexible display device.

### Description of Related Art

In today's market of various consumer electronic products, flexible display devices have been widely used as display screens in portable electronic devices, such as e-books. Since an electronic paper display device uses incident light to irradiate an electronic ink layer to achieve the purpose of display, the electronic paper display device does not need a backlight source, and can save power consumption. The incident light may be sunlight or indoor ambient light.

However, when a flexible display device is folded, slid or rolled, microcracks adjacent to the edge of a display area may extend further into the display area, resulting in defects in the display area. Although the design of strip-shaped isolation structures and strip-shaped trenches arranged alternately in parallel can be used to prevent cracks from extending to the display area, the design of the strip-shaped isolation structures and the strip-shaped grooves causes resistance to the flow of frame sealant coated on the strip-shaped i isolation structures and the strip-shaped grooves. The resistance is not conducive to the exhaust of gas in a space for the frame sealant to flow into, such that bubbles are easily formed in the frame sealant adjacent to the display area, thereby reducing adhesion and the capability of blocking water vapor. As a result, a local stress concentration area may be formed to cause peeling and delamination when materials are folded, slid or rolled.

### SUMMARY

According to some embodiments of the present disclosure, a flexible display device includes a flexible substrate, a dielectric stack, a display medium layer, a sealant, and a protection sheet. The dielectric stack includes plural dielectric layers stacked on the flexible substrate in sequence. The dielectric stack has a patterned trench to define plural island structures. Each of the island structures is surrounded by the patterned trench. The dielectric stack includes a first portion and a second portion respectively at two opposite sides of the patterned trench. The display medium layer is located on the first portion of the dielectric stack to define a display area. The sealant covers the second portion of the dielectric stack, the patterned trench, and the island structures, and extends to a sidewall of the display medium layer. The protection sheet is located on the sealant and the display medium layer.

In some embodiments, the patterned trench has a plurality of horizontal portions and a plurality of vertical portions, and two of the horizontal portions adjacent to each other are connected by at least one of the vertical portions.

In some embodiments, the island structures are arranged in a plurality of rows, and the island structures in one of the rows are aligned in a horizontal direction.

In some embodiments, a lengthwise direction of the island structures is parallel to the horizontal direction.

In some embodiments, the island structures in two of the rows adjacent to each other are misaligned in a vertical direction.

In some embodiments, the island structures are arranged in a plurality of columns, and the island structures in one of the columns are aligned in a vertical direction.

In some embodiments, a widthwise direction of the island structures is parallel to the vertical direction.

In some embodiments, a lengthwise direction of the island structures is tilted relative to a horizontal direction.

In some embodiments, the patterned trench further includes an extending portion located in the second portion of the dielectric stack.

In some embodiments, materials of the dielectric layers are different.

In some embodiments, the display medium layer includes organic light emitting diodes or electronic ink.

According to some embodiments of the present disclosure, a flexible display device includes a flexible substrate, a dielectric stack, a display medium layer, a sealant, and a protection sheet. The dielectric stack includes plural dielectric layers stacked on the flexible substrate in sequence. The dielectric stack has a patterned trench, the patterned trench is a grid shape to define a plurality of island structures of the dielectric stack, and the dielectric stack includes a first portion and a second portion respectively at two opposite sides of the patterned trench. The display medium layer is located on the first portion of the dielectric stack to define a display area. The sealant covers the second portion of the dielectric stack, the patterned trench, and the island structures, and extends to a sidewall of the display medium layer. The protection sheet is located on the sealant and the display medium layer.

In some embodiments, the patterned trench has a plurality of horizontal portions and a plurality of vertical portions, and two of the horizontal portions adjacent to each other are connected by at least one of the vertical portions.

In some embodiments, the island structures are arranged in a plurality of rows, and the island structures in one of the rows are aligned in a horizontal direction.

In some embodiments, a lengthwise direction of the island structures is parallel to the horizontal direction.

In some embodiments, the island structures in two of the rows adjacent to each other are misaligned in a vertical direction.

In some embodiments, the island structures are arranged in a plurality of columns, and the island structures in one of the columns are aligned in a vertical direction.

In some embodiments, a widthwise direction of the island structures is parallel to the vertical direction.

In some embodiments, a lengthwise direction of the island structures is tilted relative to a horizontal direction.

In some embodiments, the patterned trench further includes an extending portion located in the second portion of the dielectric stack.

In the aforementioned embodiments of the present disclosure, since the flexible display device has the dielectric stack on the flexible substrate and the dielectric stack has the patterned trench that is a grid shape to define the island structures of the dielectric stack, the island structures can be surrounded by the patterned trench. Such a design can prevent microcracks adjacent to the edge of the display area from extending further into the display area to form defects in the display area when the flexible display device is used in a foldable, slidable, or rollable display device. Moreover, the island structures and the patterned trench of the dielectric stack can reduce resistance to the flow of the sealant to flow into, and can improve gas exhaust efficiency, thereby increasing the speed of the sealant flowing into the island structures. As a result, bubbles formed by the sealant covering gas can be avoided, and adhesion and the capability of blocking water vapor can be improved, thereby improving the mechanical characteristics and product reliability of the flexible display device, and preventing the local stress concentration area of the flexible display device to cause peeling and delamination when materials are folded, slid or rolled.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view of a flexible display device according to one embodiment of the present disclosure.

FIG. 2 is a cross-sectional view of the flexible display device taken along line 2-2 of FIG. 1.

FIG. 3 is a top view of island structures and a patterned trench of a dielectric stack of FIG. 2.

FIG. 4 is a top view of island structures and a patterned trench according to another embodiment of the present disclosure.

FIG. 5 is a top view of island structures and a patterned trench according to still another embodiment of the present disclosure.

FIG. 6 is a top view of island structures and a patterned trench according to yet another embodiment of the present disclosure.

FIG. 7 is schematic view of a coating direction when coating a sealant on the island structures and the patterned trench of FIG. 6.

FIG. 8 is a top view of island structures and a patterned trench according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

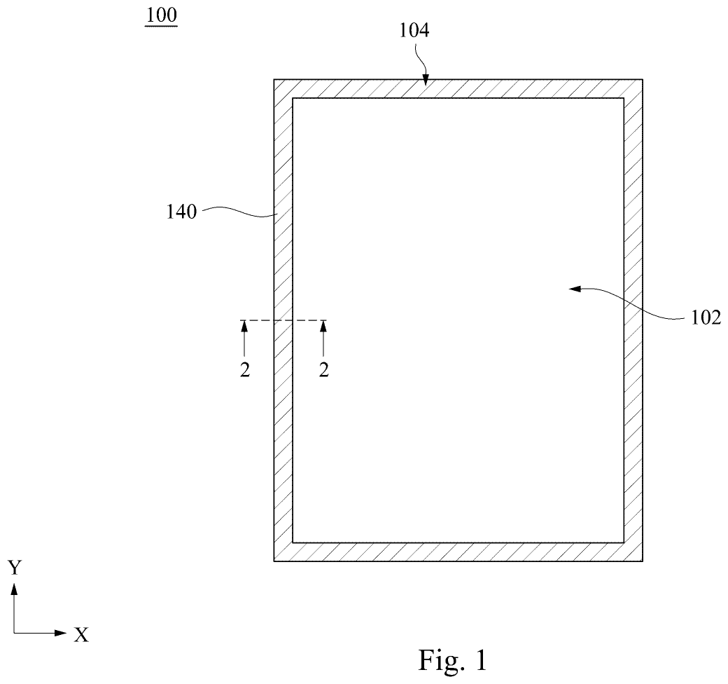

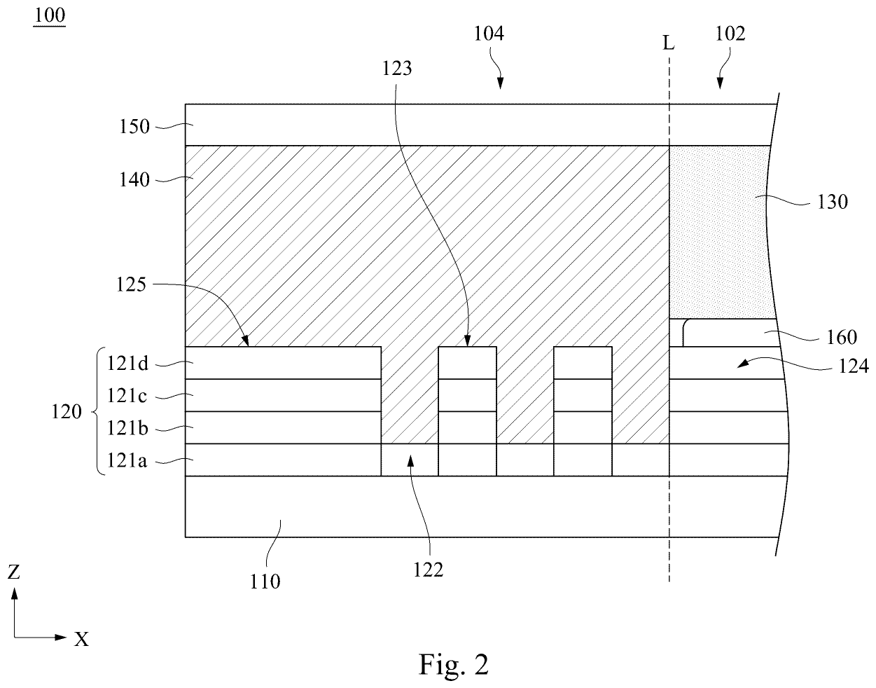

FIG. 1 is a top view of a flexible display device 100 according to one embodiment of the present disclosure. FIG. 2 is a cross-sectional view of the flexible display device 100 taken along line 2-2 of FIG. 1. As shown in FIG. 1 and FIG. 2, the flexible display device 100 includes a flexible substrate 110, a dielectric stack 120, a display medium layer 130, a sealant 140, and a protection sheet 150. The flexible display device 100 has a display area 102 and a non-display area 104 surrounding the display area 102. The flexible substrate 110 has thin film transistor (TFT) array in the display area 102. The material of the flexible substrate 110 may be, but not limited to polyimide (PI). The dielectric stack 120 includes plural dielectric layers 121a, 121b, 121c, and 121d stacked on the flexible substrate 110 in sequence. The materials of the dielectric layers 121a, 121b, 121c, and 121d may be different, such as oxide and nitride. The number of the dielectric layers shown in FIG. 2 is merely an example, and the present disclosure is not limited in this regard. The display medium layer 130 is located on the dielectric stack 120 in the display area 102 (e.g., the area at the right side of line L of FIG. 2). In some embodiments, the display medium layer 130 may include organic light emitting diodes or electronic ink, such as microcapsules or microcups having charged particles with different colors. The sealant 140 is located on the dielectric stack 120 in the non-display area 104 (e.g., the area at the left side of line L of FIG. 2). The sealant 140 is located in the non-display area 104, serves as a frame sealant, and surrounds the display medium layer 130. The protection sheet 150 is located on the sealant 140 and the display medium layer 130. The protection sheet 150 has light permeability to provide protection. The material of the protection sheet 150 may be, but not limited to polyethylene terephthalate (PET).

In the following description, the design of the dielectric stack 120 will be explained in detail.

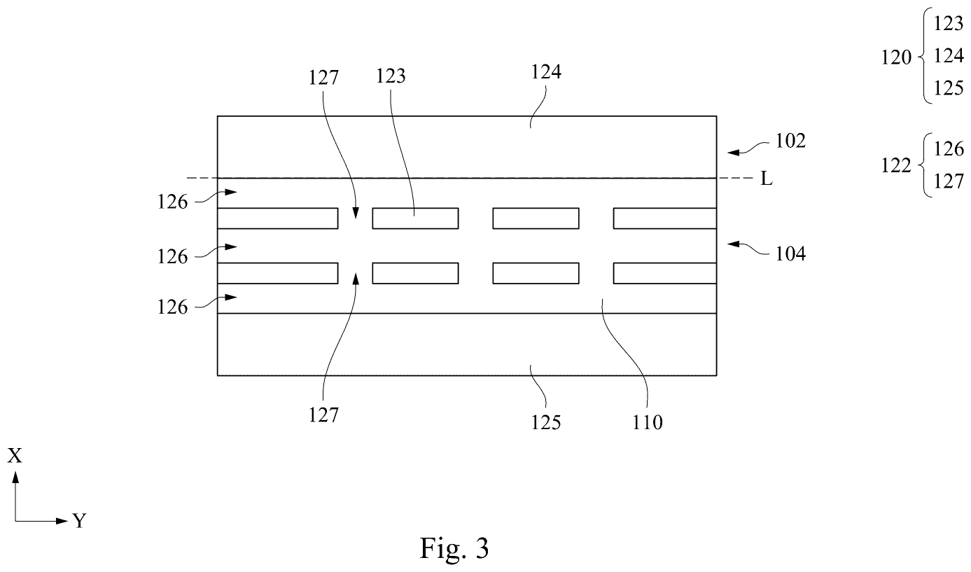

FIG. 3 is a top view of island structures 123 and a patterned trench 122 of the dielectric stack 120 of FIG. 2. As shown in FIG. 2 and FIG. 3, the dielectric stack 120 has the patterned trench 122 to define the island structures 123. The patterned trench 122 is a grid shape, and each of the island structures 123 is surrounded by the patterned trench 122. In this embodiment, the patterned trench 122 has a plurality of horizontal portions 126 and a plurality of vertical portions 127, and two of the horizontal portions 126 adjacent to each other are connected by the vertical portion 127. The island structures 123 are arranged in plural rows and plural columns. The patterned trench 122 is a symmetric opening, such that the island structures 123 in one of the rows are aligned in a horizontal direction (e.g., a direction Y), and the island structures 123 in one of the columns are aligned in a vertical direction (e.g., a direction X). In addition, the lengthwise direction of the island structures 123 is parallel to the horizontal direction. The widthwise direction of the island structures 123 is parallel to the vertical direction. The island structures 123 shown in FIG. 3 are arranged in two rows and three columns, but the number of rows and the number of columns are merely an example, and the present disclosure is not limited in this regard.

The dielectric stack 120 includes a first portion 124 and a second portion 125 respectively at two opposite sides of the patterned trench 122. The display medium layer 130 is located on the first portion 124 of the dielectric stack 120, and is configured to define the display area 102. The sealant 140 covers the second portion 125 of the dielectric stack 120, the patterned trench 122, and the island structures 123, and extends to the sidewall of the display medium layer 130. The sealant 140 abuts against the display medium layer 130 so as to be in contact with each other. When coating the sealant 140, the sealant 140 may flow into the patterned trench 122, such that the patterned trench 122 may be partially filled with the sealant 140 or filled with the sealant 140. In this embodiment, there is an isolation layer 160 located between the display medium layer 130 and the first portion 124 of the dielectric stack 120, and the material of the isolation layer 160 is resin, for example.

Specifically, since the flexible display device 100 has the dielectric stack 120 on the flexible substrate 110 and the dielectric stack 120 has the patterned trench 122 that is a grid shape to define the island structures 123 of the dielectric stack 120, the island structures 123 can be surrounded by the patterned trench 122. Such a design can prevent microcracks adjacent to the edge of the display area 102 from extending further into the display area 102 to form defects in the display area 102 when the flexible display device 100 is used in a foldable, slidable, or rollable display device. Moreover, the island structures 123 and the patterned trench 122 of the dielectric stack 120 can reduce resistance to the flow of the sealant 140 to flow into, and can improve gas exhaust efficiency, thereby increasing the speed of the sealant 140 flowing into the island structures 123. As a result, bubbles formed by the sealant 140 covering gas can be avoided, and adhesion and the capability of blocking water vapor can be improved, thereby improving the mechanical characteristics and product reliability of the flexible display device 100, and preventing the local stress concentration area of the flexible display device 100 to cause peeling and delamination when materials are folded, slid or rolled.

It is to be noted that the connection relationships, the materials, and the advantages of the elements described above will not be repeated in the following description. In the following description, other types of island structures and patterned trenches will be explained.

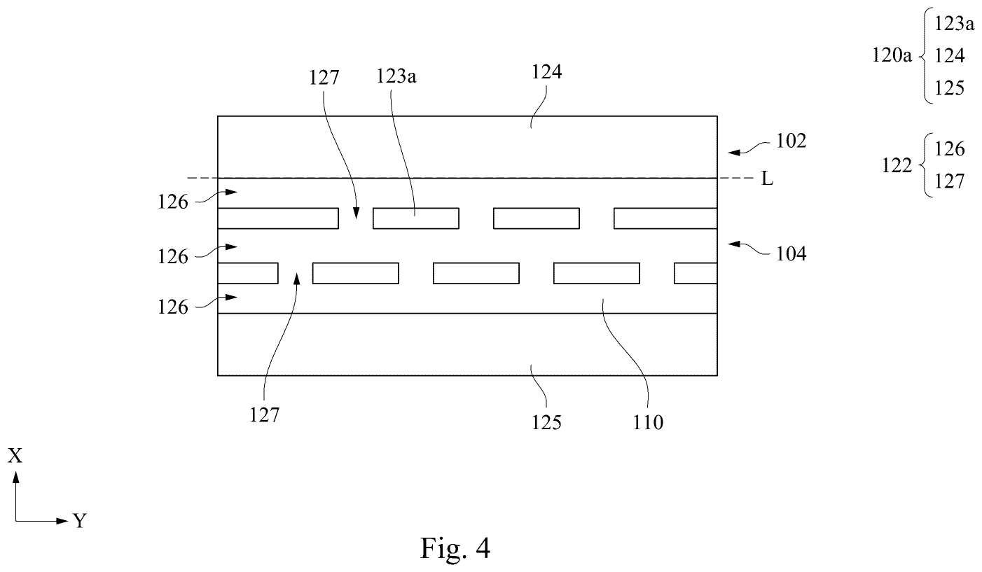

FIG. 4 is a top view of island structures 123a and the patterned trench 122 according to another embodiment of the present disclosure. A dielectric stack 120a has the island structures 123a and the patterned trench 122. The difference between this embodiment and the embodiment of FIG. 3 is that the patterned trench 122 of FIG. 4 is an asymmetric opening, such that the island structures 123a in two of the rows adjacent to each other are misaligned in a vertical direction (e.g., the direction X). In other words, the island structures 123a in two of the rows adjacent to each other are arranged in a staggered manner.

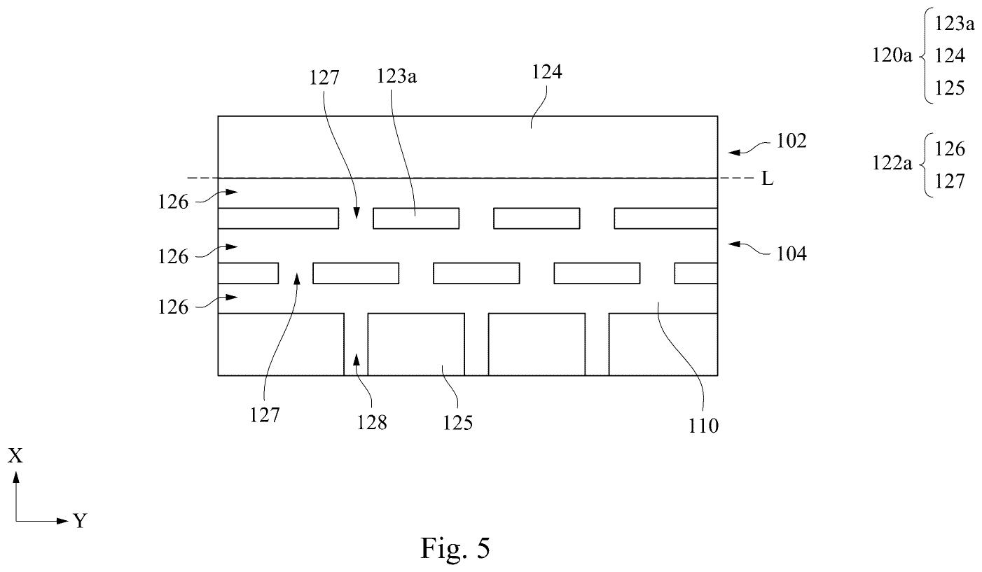

FIG. 5 is a top view of the island structures 123a and a patterned trench 122a according to still another embodiment of the present disclosure. The dielectric stack 120a has the island structures 123a and the patterned trench 122a. The difference between this embodiment and the embodiment of FIG. 4 is that the patterned trench 122a further includes an extending portion 128 located in the second portion 125 of the dielectric stack 120a. If the sealant 140 (see FIG. 2) has a better capability of blocking water vapor, the second portion 125 of the dielectric stack 120a adjacent to the outer edge of the display device may further have opening design, such that the extending portion 128 of the patterned trench 122a increases the fluidity of the sealant 140 and the fluidity of gas.

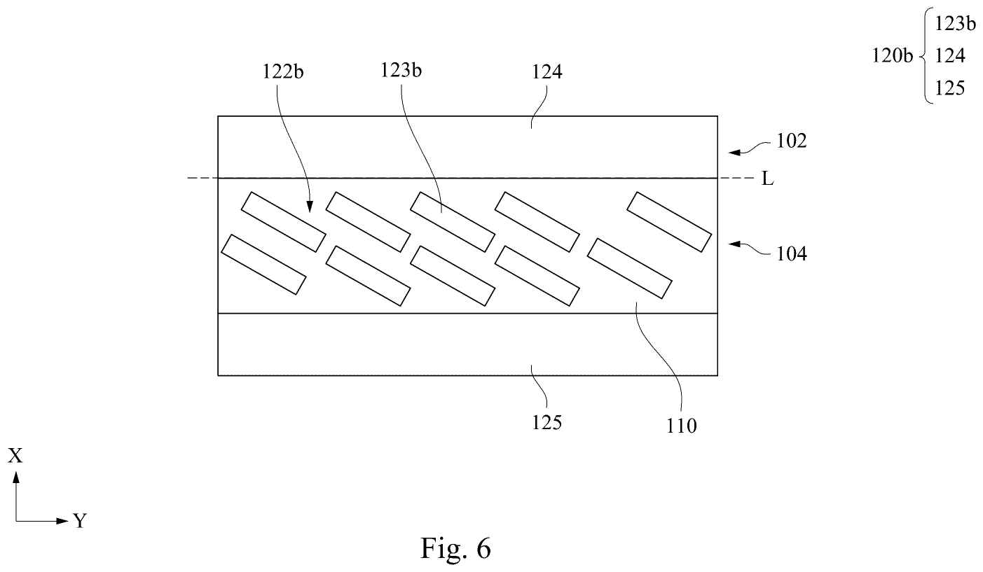

FIG. 6 is a top view of island structures 123b and a patterned trench 122b according to yet another embodiment of the present disclosure. The dielectric stack 120b has the island structures 123b and the patterned trench 122b. The difference between this embodiment and the embodiment of FIG. 3 is that the lengthwise direction of the island structures 123b is tilted relative to a horizontal direction (e.g., the direction Y). The tilted island structures 123b can increase the fluidity of the sealant 140 (see FIG. 2) coated in the patterned trench 122b and the fluidity of gas originally located in the patterned trench 122b.

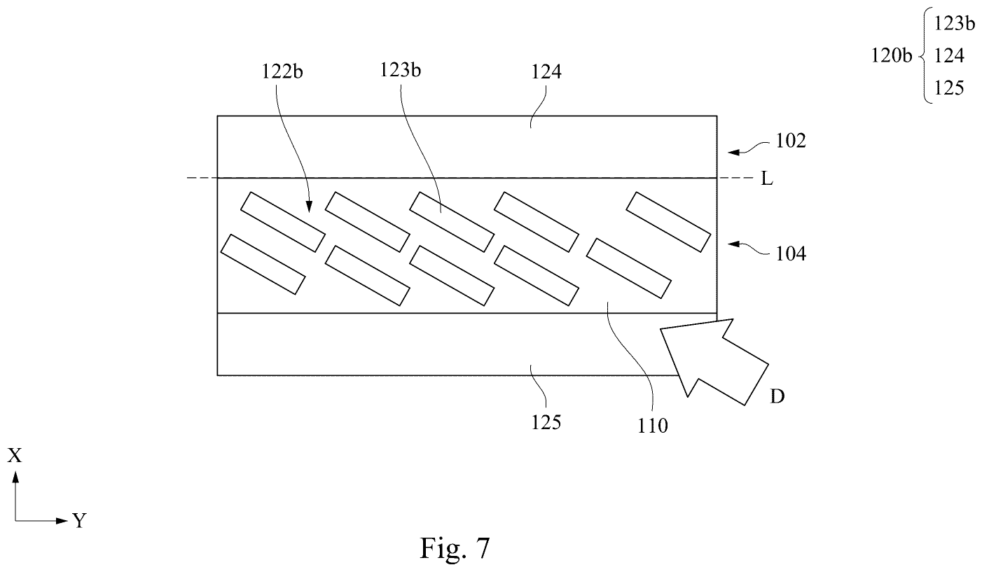

FIG. 7 is schematic view of a coating direction D when coating the sealant 140 (see FIG. 2) on the island structures 123b and the patterned trench 122b of FIG. 6. Before coating the sealant 140, the lengthwise direction (i.e., a tilt direction) of the island structures 123b may be designed to be parallel to the coating and infiltration direction D. Such a design can further increase the fluidity of the sealant 140 and the fluidity of gas to prevent forming bubbles when coating the sealant 140.

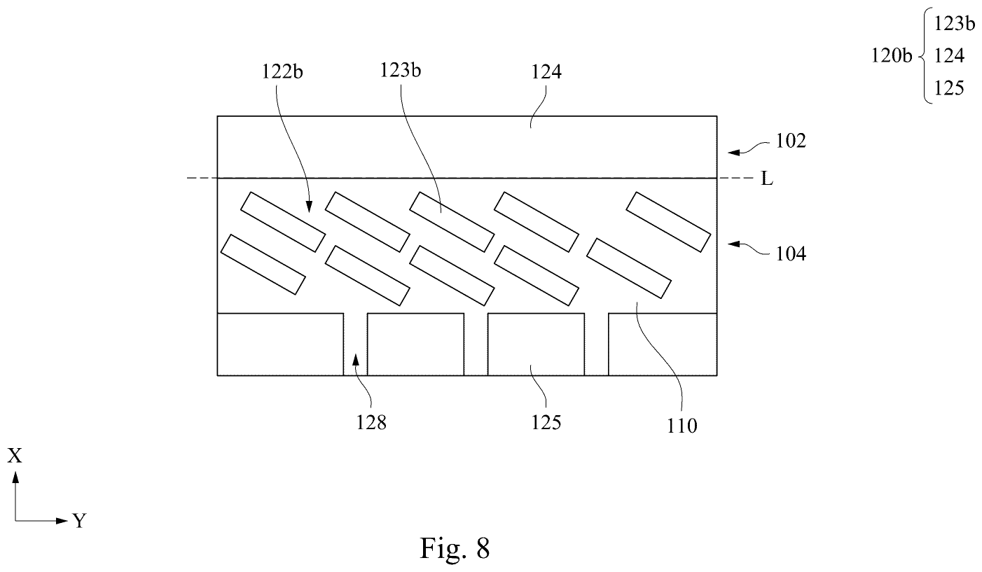

FIG. 8 is a top view of the island structures 123b and the patterned trench 122b according to one embodiment of the present disclosure. The dielectric stack 120b has the island structures 123b and the patterned trench 122b. The difference between this embodiment and the embodiment of FIG. 7 is that the patterned trench 122b further includes the extending portion 128 located in the second portion 125 of the dielectric stack 120b. If the sealant 140 (see FIG. 2) has a better capability of blocking water vapor, the second portion 125 of the dielectric stack 120b adjacent to the outer edge of the display device may further have opening design, such that the extending portion 128 of the patterned trench 122b increases the fluidity of the sealant 140 and the fluidity of gas.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A flexible display device, comprising:
a flexible substrate;
a dielectric stack comprising a plurality of dielectric layers stacked on the flexible substrate in sequence, wherein the dielectric stack has a patterned trench to define a plurality of island structures surrounded by the patterned trench, and the dielectric stack comprises a first portion and a second portion respectively at two opposite sides of the patterned trench;
a display medium layer located on the first portion of the dielectric stack and configured to define a display area;
a sealant covering the second portion of the dielectric stack, the patterned trench, and the island structures, and extending to a sidewall of the display medium layer; and
a protection sheet located on the sealant and the display medium layer.

2. The flexible display device of claim 1, wherein the patterned trench has a plurality of horizontal portions and a plurality of vertical portions, and two of the horizontal portions adjacent to each other are connected by at least one of the vertical portions.

3. The flexible display device of claim 1, wherein the island structures are arranged in a plurality of rows, and the island structures in one of the rows are aligned in a horizontal direction.

4. The flexible display device of claim 3, wherein a lengthwise direction of the island structures is parallel to the horizontal direction.

5. The flexible display device of claim 3, wherein the island structures in two of the rows adjacent to each other are misaligned in a vertical direction.

6. The flexible display device of claim 1, wherein the island structures are arranged in a plurality of columns, and the island structures in one of the columns are aligned in a vertical direction.

7. The flexible display device of claim 6, wherein a widthwise direction of the island structures is parallel to the vertical direction.

8. The flexible display device of claim 1, wherein a lengthwise direction of the island structures is tilted relative to a horizontal direction.

9. The flexible display device of claim 1, wherein the patterned trench further comprises an extending portion located in the second portion of the dielectric stack.

10. The flexible display device of claim 1, wherein materials of the dielectric layers are different.

11. The flexible display device of claim 1, wherein the display medium layer comprises organic light emitting diodes or electronic ink.

12. A flexible display device, comprising:
a flexible substrate;
a dielectric stack comprising a plurality of dielectric layers stacked on the flexible substrate in sequence, wherein the dielectric stack has a patterned trench, the patterned trench is a grid shape to define a plurality of island structures of the dielectric stack, and the dielectric stack comprises a first portion and a second portion respectively at two opposite sides of the patterned trench;
a display medium layer located on the first portion of the dielectric stack and configured to define a display area;
a sealant covering the second portion of the dielectric stack, the patterned trench, and the island structures, and extending to a sidewall of the display medium layer; and
a protection sheet located on the sealant and the display medium layer.

13. The flexible display device of claim 12, wherein the patterned trench has a plurality of horizontal portions and a plurality of vertical portions, and two of the horizontal portions adjacent to each other are connected by at least one of the vertical portions.

14. The flexible display device of claim 12, wherein the island structures are arranged in a plurality of rows, and the island structures in one of the rows are aligned in a horizontal direction.

15. The flexible display device of claim 14, wherein a lengthwise direction of the island structures is parallel to the horizontal direction.

16. The flexible display device of claim 14, wherein the island structures in two of the rows adjacent to each other are misaligned in a vertical direction.

17. The flexible display device of claim 12, wherein the island structures are arranged in a plurality of columns, and the island structures in one of the columns are aligned in a vertical direction.

18. The flexible display device of claim 17, wherein a widthwise direction of the island structures is parallel to the vertical direction.

19. The flexible display device of claim 12, wherein a lengthwise direction of the island structures is tilted relative to a horizontal direction.

20. The flexible display device of claim 12, wherein the patterned trench further comprises an extending portion located in the second portion of the dielectric stack.
